(19) United States
(12) Patent Application Publication
(10) Pub. No.: US 2023/0411552 A1
(43) Pub. Date: Dec. 21, 2023

(54) WIRE JIG AND TABBING APPARATUS INCLUDING THE WIRE JIG

(71) Applicant: HANWHA CORPORATION, Seoul (KR)

(72) Inventors: Sung Gyu JEON, Sioul (KR); Dong Jin Chung, Seoul (KR); Min Kyo Jung, Seoul (KR)

(73) Assignee: HANWHA CORPORATION, Seoul (KR)

(21) Appl. No.: 18/210,231

(22) Filed: Jun. 15, 2023

(30) Foreign Application Priority Data
Jun. 16, 2022 (KR) 10-2022-0073451

(51) Int. Cl. H01L 31/18

(52) U.S. Cl. CPC H01L 31/188

(57) ABSTRACT

A wire jig provided configured to support a plurality of wires includes: a body frame having a window on an inside of the body portion; and a plurality of supporting frames arranged to correspond to the window, each supporting frame comprising a plurality of supporting elements contacting the plurality of wires, and arranged to form n rows (n is a natural number greater than 1) in a width direction of the body frame, wherein the plurality of supporting frames are sequentially arranged from a 1^{st} row to an n^{th} row, and the plurality of supporting elements included in any one of the supporting frames have a different arrangement from the plurality of supporting elements included in at least one of the other supporting frames.

### CROSS-REFERENCE TO RELATED APPLICATION

This application is based on and claims priority under 35 U.S.C. § 119 to Korean Patent Application No. 10-2022-0073451, filed on Jun. 16, 2022, in the Korean Intellectual Property Office, the disclosure of which is incorporated by reference herein in its entirety.

### BACKGROUND

### 1. Field

Example embodiments of the disclosure relates to a wire jig and a tabbing apparatus including the wire jig.

### 2. Description of the Related Art

A solar cell is formed by arranging a p-n junction diode on a substrate. When a solar cell is irradiated with sunlight, excitons, which are electron-hole pairs, are generated. As the excitons are separated, electrons move to an n-layer and holes move to a p-layer, thereby generating photovoltaic power at a p-n junction. Tabbing is a process of forming one solar cell module by electrically connecting a plurality of solar cells to each other by arranging wires to the plurality of solar cells.

A tabbing apparatus includes a conveying apparatus for conveying a wire, and bonds a solar cell and a wire to each other in a state where the solar cell is arranged on the wire. In this process, displacement occurs in the wire, such as the wire lifts or the wire is separated from a designated position, and as a result, the wire and the solar cell may not be connected at a desired position or the connection therebetween may be poor.

Also, in the case of the related art in which an apparatus for supporting wires, the number of wires, intervals between wires, and distances between contact points between the wires and a wire supporting apparatus are all uniformly determined, so the wires cannot be efficiently supported.

The background art stated above is technical information that the inventor possessed for derivation of the disclosure or acquired during the derivation process of the disclosure, and cannot necessarily be said to be known art disclosed to the general public prior to filing the disclosure.

### SUMMARY

Provided are a wire jig capable of supporting a wire when connecting a solar cell and a wire to each other, and connecting the solar cell and the wire well, and a tabbing apparatus including the wire jig, wherein supporting frames for supporting wires are arranged in a certain pattern to efficiently support the wires.

Additional aspects will be set forth in part in the description which follows and, in part, will be apparent from the description, or may be learned by practice of the presented embodiments of the disclosure.

According to an aspect of the disclosure, a wire jig configured to support a plurality of wires includes: a body frame having a window on an inside of the body portion; and a plurality of supporting frames arranged to correspond to the window, each supporting frame comprising a plurality of supporting elements contacting the plurality of wires, and arranged to form n rows (n is a natural number greater than 1) in a width direction of the body frame, wherein the plurality of supporting frames are sequentially arranged from a 1^{st} row to an n^{th} row, and the plurality of supporting elements included in any one of the supporting frames have a different arrangement from the plurality of supporting elements included in at least one of the other supporting frames.

In the wire jig according to an embodiment, each of the plurality of supporting elements includes a body, and at least one contact member arranged on a lower surface of the body, the lower surface facing the wire, and protruding toward the wire.

In the wire jig according to an embodiment, a number of supporting elements included in each of the supporting frame of the 1^{St} row and the supporting frame of the n^{th} row is greater than a number of supporting elements included in another supporting frame.

In the wire jig according to an embodiment, the plurality of supporting elements included in the supporting frame of the 1^{st} row are in the same number and arrangement as the plurality of supporting elements included in the supporting frame of the n^{th} row.

In the wire jig according to an embodiment, the plurality of supporting elements included in the supporting frame of each of the 1^{st} row and the supporting frame of the n^{th} row have a smaller number of contact members than the plurality of supporting elements included in each of the other supporting frames.

In the wire jig according to an embodiment, the plurality of supporting frames include: a plurality of first supporting frames each of which comprises a plurality of supporting elements, each having two contact members; and a plurality of second supporting frames each of which comprises a plurality of second supporting elements, each having two contact members and arranged to overlap two adjacent first supporting elements included in each of the first supporting frames in a width direction of the body frame.

In the wire jig according to an embodiment, the plurality of first supporting frames and the plurality of second supporting frames are alternately arranged.

In the wire jig according to an embodiment, each of the plurality of second supporting frames further includes a pair of third supporting elements arranged at both ends in a longitudinal direction of the body frame to arrange the plurality of second supporting elements between the pair of third supporting elements, and each of the third supporting elements has one contact member.

In the wire jig according to an embodiment, the plurality of supporting elements included in at least one supporting frame are arranged zigzag with the plurality of supporting elements included in an adjacent supporting frame in a width direction of the body frame.

According to another aspect of the disclosure, a tabbing apparatus configured to connect a solar cell and a wire to each other, and includes a wire jig configured to support the wire and a transport apparatus configured to move the wire jig, wherein the wire jig is configured to support a plurality of wires, the wire jig including: a body frame having a window therein; and a plurality of supporting frames arranged to correspond to the window, comprising a plurality of supporting elements configured to contact the plurality of wires, and arranged to form n rows (n is a natural number greater than 1) in a width direction of the body frame, wherein the plurality of supporting frames are sequentially arranged from a 1^{St} row to an n^{th} row, and the plurality of supporting elements included in any one of the supporting frames in the 1^{st} row to the n^{th} row have a different arrangement from the plurality of supporting elements included in at least one of the other supporting frames.

Other aspects, features, and advantages other than those described above will become clear from the detailed description, claims, and drawings for carrying out the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 schematically illustrates a tabbing apparatus according to an embodiment;

FIG. 2 illustrates a front perspective view of a wire jig according to an embodiment;

FIG. 3 illustrates a rear perspective view of a wire jig according to an embodiment;

FIG. 4 illustrates a supporting frame according to an embodiment;

FIG. 5 illustrates an enlarged view of a supporting element according to an embodiment;

FIGS. 6 and 7 show an operation of a wire jig according to an embodiment; and

FIGS. 8A and 8B to 11A and 11B show supporting frames according to other embodiments and a wire support state according to the supporting frames.

### DETAILED DESCRIPTION

Reference will now be made in detail to embodiments, examples of which are illustrated in the accompanying drawings, wherein like reference numerals refer to like elements throughout. The present embodiments are example embodiments, and thus, may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

According to an embodiment, a wire jig and a tabbing apparatus including the wire jig may include various embodiments and modifications, and hereinafter, some embodiments are shown in drawings and described in the description of the disclosure. However, the disclosure is not limited to the following embodiments, and includes all conversions, equivalents, and substitutes included in the spirit and technical scope of the disclosure.

In the following embodiments, while such terms as “first,” “second,” etc., may be used to describe various components, such components must not be limited to the above terms. The above terms are used only to distinguish one component from another. An expression used in the singular encompasses the expression of the plural, unless it has a clearly different meaning in the context. Also, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added. In addition, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

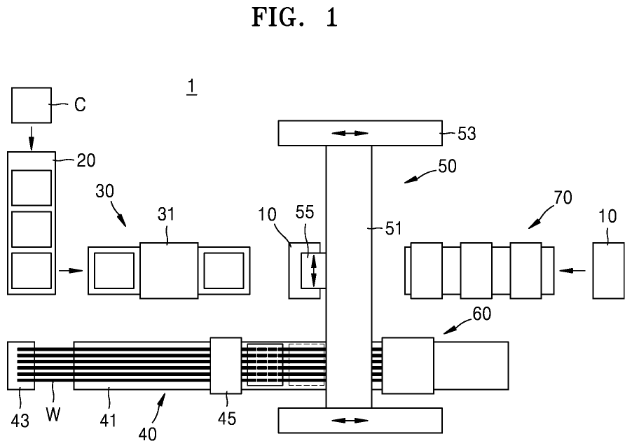

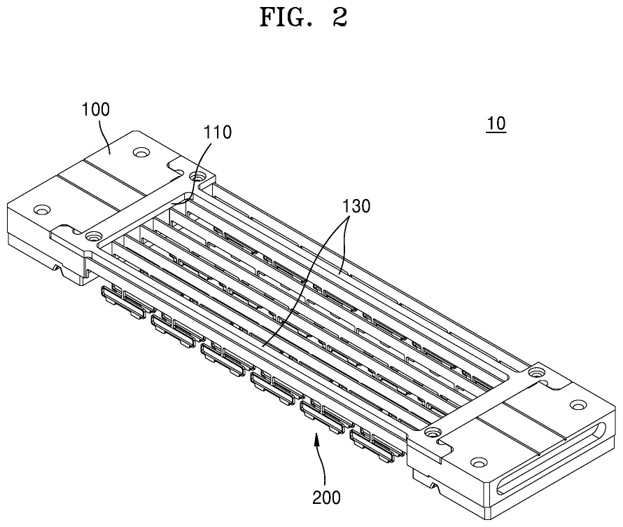

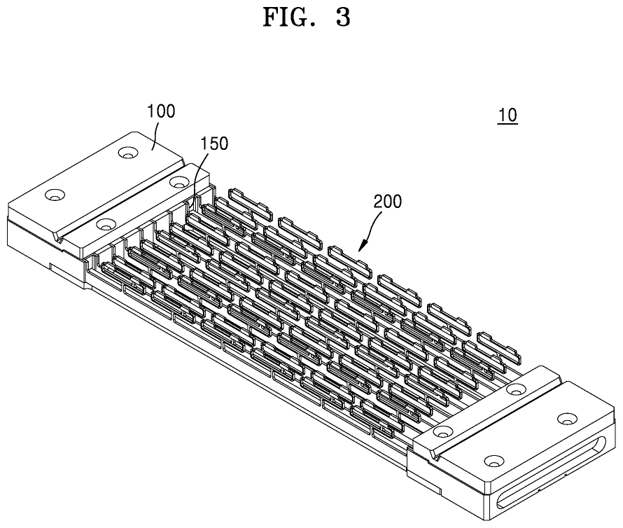

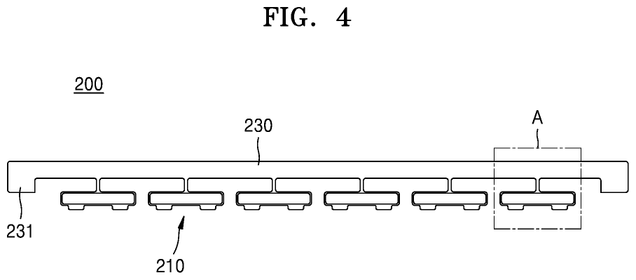

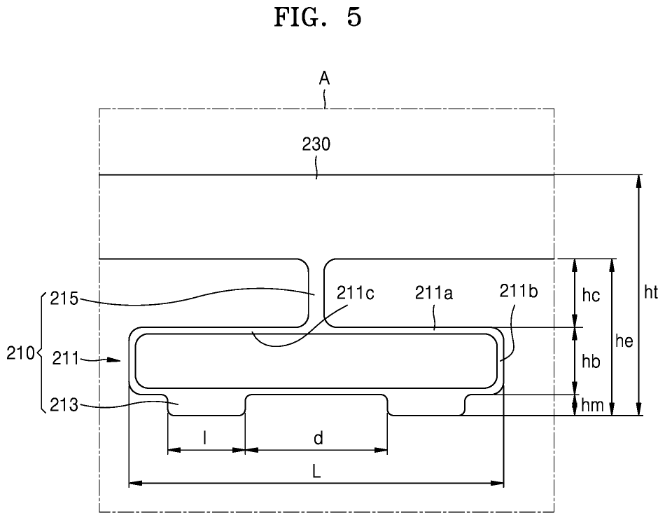

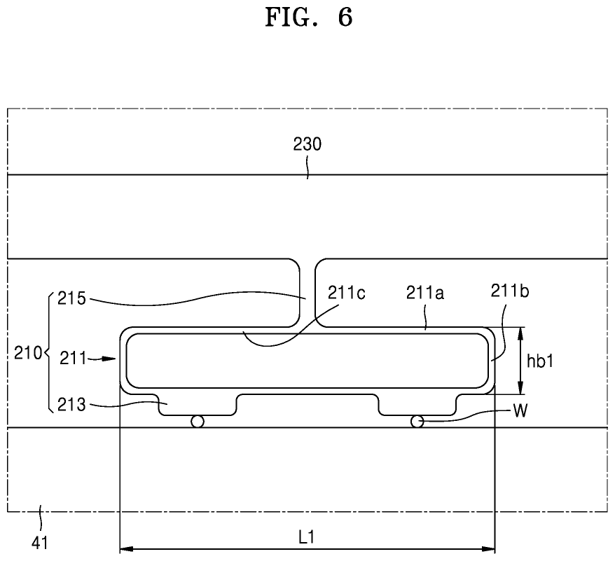

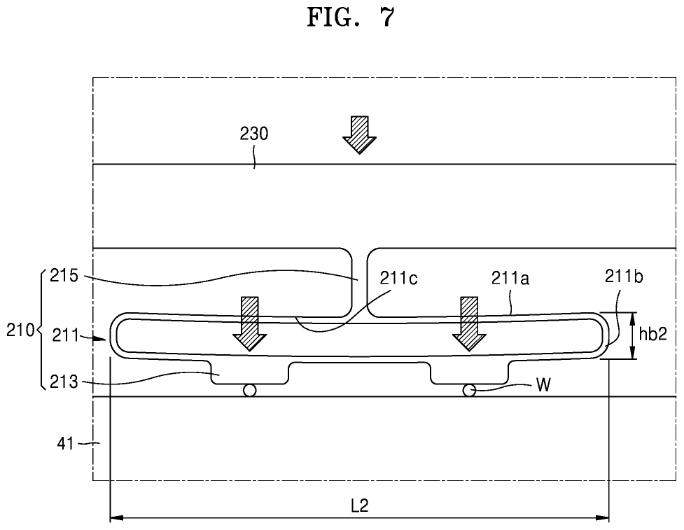

FIG. 1 schematically illustrates a tabbing apparatus 1 according to an embodiment, FIG. 2 illustrates a front perspective view of a wire jig 10 according to an embodiment, FIG. 3 illustrates a rear perspective view of the wire jig 10 according to an embodiment, FIG. 4 illustrates a supporting frame 200 according to an embodiment, FIG. 5 illustrates an enlarged view of a supporting element 210 according to an embodiment, and FIGS. 6 and 7 show an operation of the wire jig 10 according to an embodiment.

The tabbing apparatus 1 is an apparatus for forming a solar cell module by connecting a solar cell C and a wire W to each other. The solar cell C has a semiconductor junction region having a p-n junction surface, and when energy of a certain level or more is irradiated to the solar cell C, an electromotive force is generated to convert light energy into electrical energy. A material of a semiconductor included in the solar cell C is not particularly limited, and silicon (single crystal silicon, polycrystalline silicon, and amorphous silicon), gallium arsenide, cadmium tellurium, cadmium sulfide, indium phosphorus, copper indium gallium selenide (CIGS), organic dyes, or mixtures thereof may be used.

The wire W is a conductor for electrically connecting a plurality of solar cells C to each other, and connects a front surface of a solar cell C with a rear surface of an adjacent solar cell C. For example, the wire W may be electrically connected to the solar cell C through a soldering process. Alternatively, the wire W may be electrically connected to the solar cell C through an electrically conductive adhesive (ECA).

In an embodiment, a diameter of the wire W may be about 0.1 mm to about 0.5 mm. The diameter of the wire W may be about 0.15 mm to about 0.45 mm. The diameter of the wire W may be about 0.2 mm to about 0.4 mm. For example, the diameter of the wire W may be about 0.26 mm to about 0.38 mm.

In an embodiment, as shown in FIG. 1, the tabbing apparatus 1 may include the wire jig 10, a solar cell conveying apparatus 20, a solar cell dividing apparatus 30, a wire conveying apparatus 40, a transport apparatus 50, a bonding apparatus 60, and a wire jig conveying apparatus 70.

The wire jig 10 is put in the tabbing apparatus 1 by the wire jig conveying apparatus 70 arranged on one side of the tabbing apparatus 1. The wire jig 10 maintains the position of the wire W during a tabbing process so that the solar cell C and the wire W are coupled well to each other. The wire jig 10 is described in detail below.

The solar cell conveying apparatus 20 receives and conveys the solar cell C from the outside. For example, the solar cell conveying apparatus 20 including a conveyor may move the solar cell C to the solar cell dividing apparatus 30. Here, the solar cell C may be in a state of not being divided (scribed) into a certain size.

The solar cell dividing apparatus 30 may divide the solar cell C received from the solar cell conveying apparatus 20 according to a required size. For example, the solar cell dividing apparatus 30 may include a scriber 31, and the scriber 31 may divide the solar cell C into a plurality of segments by using laser or a mechanical method.

The wire conveying apparatus 40 receives and moves the wire conveying apparatus 40 from the outside. For example, the wire conveying apparatus 40 may include a conveyor 41, a roller 43, and an aligner 45.

The conveyor 41 may have a flat surface so that a plurality of wires W may move while being spaced apart from each other. The roller 43 is arranged at an end portion of the wire conveying apparatus 40 so that the wire W is conveyed while seated on an upper surface of the conveyor 41. The rollers 43 may be respectively arranged on one side and another side of the wire conveying apparatus 40 so that the conveyor 41 is arranged therebetween. The aligner 45 primarily aligns the position of the wire W before the wire W contacts the solar cell C, that is, before the solar cell C is arranged on the wire W. For example, the aligner 45 may have a number of grooves or protrusions corresponding to the plurality of wires W, so that the wires W move along a designated path.

The transport apparatus 50 moves the solar cell C and the wire jig 10 to the wire W. In an embodiment, the transport apparatus 50 may include a first frame 51, a second frame 53, and a transport head 55. The first frame 51 and the second frame 53 are arranged to cross each other, and the first frame 51 may be configured to be movable between a pair of second frames 53. Also, the transport head 55 is arranged on one side of the first frame 51 to be movable along the first frame 51, and may pick up an object in a suction method, a method using an electromagnetic force, or a mechanical method.

In an embodiment, the transport head 55 may move on the wire W in a state of the solar cell C and the wire jig 10 being picked up by the transport head 55 to sit the solar cell C and the wire jig 10 on the wire W. For example, as shown in FIG. 1, the transport head 55 may pick up the solar cell C divided by the solar cell dividing apparatus 30 to arrange the same on the wire W. Also, the transport head 55 may pick up the wire jig 10 conveyed by the wire jig conveying apparatus 70 and arrange the same on the wire W. The transport head 55 may place the solar cell C on the wire W in a state where the wire W is held and fixed at a position by contacting the wire jig 10 with the wire W.

In an embodiment, the wire jig 10 may move a constant distance or more together with the wire W on the wire conveying apparatus 40 while holding the wire W.

The bonding apparatus 60 may bond the solar cell C and the wire W in a state of contacting each other. For example, the bonding apparatus 60 may be a soldering apparatus that applies solder on a connection portion or interface between the solar cell C and the wire W and then heats the solder to bond the solar cell C and the wire W to each other. Alternatively or additionally, the bonding apparatus 60 may be an apparatus that applies an ECA on a connection portion or interface between the solar cell C and the wire W to bond the solar cell C and the wire W to each other.

Referring to FIGS. 1 to 7 again, the wire jig 10 according to an embodiment is described.

The wire jig 10 may include a body frame 100 and a supporting frame 200.

The body frame 100 may form the whole frame of the wire jig 10, and the supporting frame 200 may be arranged on one side thereof. The shape of the body frame 100 is not particularly limited, and as shown in FIG. 2, the body frame 100 may have a thin hexahedral shape as a whole.

In an embodiment, the body frame 100 may have a window 110 inside the body frame 100. The window 110 may be arranged to overlap at least a portion of a region where a plurality of supporting frames 200 described below are arranged. Accordingly, even when the shape of the supporting frame 200 deforms and displacement occurs in a height direction as the wire W is pressed, the supporting frame 200 may be prevented from interfering with the body frame 100. In an embodiment, the window 110 may be formed between both ends of the body frame 100 in a longitudinal direction of the body frame 100.

The body frame 100 may have a support rib 130. As shown in FIG. 2, the support rib 130 may be arranged on the window 110 to connect both ends of the body frame 100 in the longitudinal direction of the body frame 100 to each other. In an embodiment, a pair of support ribs 130 may be arranged to be spaced apart from each other in a width direction. The support rib 130 may prevent the wire jig 10 from being twisted or damaged as the wire W is pressed. In an embodiment, each support rib 130 may be arranged not to overlap the supporting frame 200. That is, the support rib 130 may be arranged between the plurality of supporting frames 200.

The body frame 100 may have an insertion groove 150. As shown in FIG. 3, the insertion groove 150 may be formed inside the body frame 100, for example, inside both ends of the body frame 100 in the longitudinal direction of the body frame 100. An insertion protrusion 231 of the supporting frame 200 to be described below may be inserted in the insertion groove 150. For example, the insertion groove 150 is open downward and may be blocked upward. Accordingly, the supporting frame 200 may be inserted below the body frame 100 to be inserted into the insertion groove 150.

In an embodiment, the insertion groove 150 may have a shape in which a width thereof decreases downward. That is, the insertion groove 150 may have a V-shape downward in a thickness direction of the body frame 100. Accordingly, after the supporting frame 200 is inserted into the insertion groove 150, the supporting frame 200 may be prevented from being separated while the wire jig 10 presses the wire W.

The number of insertion grooves 150 may be equal to the number of supporting frames 200, and a pair of insertion grooves 150 may be arranged to face each other around the window 110.

The supporting frame 200 supports the wire W according to an operation of the wire jig 10. For example, when the wire jig 10 is picked up by the transport head 55 of the transport apparatus 50 to be moved to a designated position on the wire W and then descends, the wire jig 10 presses and supports the wire W. The supporting frame 200 prevents the wire W from being lifted or separated from a designated position during transport, so that the solar cell C and the wire W may be coupled well to each other.

In an embodiment, the supporting frame 200 may be arranged to correspond to one side of the body frame 100, for example, the window 110. For example, as shown in FIGS. 2 and 3, one or more supporting frames 200 may be provided and arranged in a region corresponding to the window 110.

In an embodiment, a plurality of supporting frames 200 may be provided. For example, as shown in FIGS. 2 and 3, a plurality of support frames 200 may be arranged to be spaced apart from each other in the width direction of the wire jig 10. Accordingly, the plurality of support frames 200 are arranged to be spaced apart from each other at certain intervals in the longitudinal direction of the wire W, so that the plurality of support frames 200 may support the wire W over a wide region.

In an embodiment, a height of the supporting frame 200 may be about 10 mm to about 30 mm. In an embodiment, the height of the supporting frame 200 may be about 15 mm to about 25 mm. In an embodiment, the height of the supporting frame 200 may be about 17 mm to about 20 mm. For example, the height of the supporting frame 200 may be 18.62 mm.

In an embodiment, a length of the supporting frame 200 may be about 100 mm to about 300 mm. In an embodiment, the length of the supporting frame 200 may be about 150 mm to about 250 mm. In an embodiment, the length of the supporting frame 200 may be about 190 mm to about 200 mm. For example, the length of the supporting frame 200 may be 195.75 mm.

In an embodiment, a thickness of the supporting frame 200 may be about 0.1 mm to about 3 mm. In an embodiment, the thickness of the supporting frame 200 may be about 0.5 mm to about 2 mm. In an embodiment, the thickness of the supporting frame 200 may be about 0.7 mm to about 1.5 mm. For example, the thickness of the supporting frame 200 may be 1 mm.

In an embodiment, the shape of the supporting frame 200 may be deformed by contact with the wire W. For example, the supporting frame 200 may include an elastic member.

In an embodiment, a material of the supporting frame 200 may be a metal. For example, the supporting frame 200 may include alloy steel, for example, high-speed steel, which is a type of high-speed tool steel. In an embodiment, the supporting frame 200 may include SKH9 high-speed steel. In an embodiment, the supporting element 210 and a guide 230, which are described below, of the supporting frame 200 may also include the same material.

In an embodiment, an elastic modulus of the supporting frame 200 may be about 10*106 psi to about 100*106 psi. In an embodiment, the elastic modulus of the supporting frame 200 may be about 20*106 psi to about 60*106 psi. In an embodiment, the elastic modulus of the supporting frame 200 may be about 30*106 psi to about 50*106 psi. For example, the elastic modulus of the supporting frame 200 may be 40*106 psi.

In an embodiment, the supporting frame 200 may include the supporting element 210 and the guide 230.

The supporting element 210 directly supports the wire W. For example, one or more supporting elements 210 are arranged on the supporting frame 200, and as the wire jig descends toward the wire W, the wire jig 10 contacts the wire W and presses the wire W against an upper surface of the conveyor 41.

In an embodiment, a plurality of supporting elements 210 may be provided. As shown in FIGS. 2 and 3, a plurality of supporting elements 210 may be provided to be spaced apart from each other in the longitudinal direction of the wire jig 10. Respective supporting elements 210 may support different wires W. Although six supporting elements 210 are shown in the drawing, the number thereof is not particularly limited thereto, and for example, two or more supporting elements 210 may be provided.

In an embodiment, the supporting element 210 may support one or more wires W. For example, the supporting element 210 may be arranged to correspond to two wires W adjacent to each other.

In an embodiment, the shape of the supporting element 210 may be changed according to a contact state with the wire W. For example, the supporting element 210 may maintain its original shape while not in contact with the wire W. Also, when the supporting element 210 contacts the wire W, the shape of the supporting element 210 may be deformed according to a contact force. Accordingly, the supporting element 210 may more strongly press the wire W by a force to restore the original shape thereof.

In an embodiment, the supporting element 210 may be an elastic member. For example, the supporting element 210 may be compressed when in contact with the wire W and may press the wire W with its restoring force. Also, the supporting element 210 may be restored to its original shape when separated from the wire W.

In an embodiment, a height he of the supporting element 210 may be 50% or more of a height ht of the supporting frame 200. In an embodiment, the height he of the supporting element 210 may be about 55% to about 75% of the height ht of the supporting frame 200. When the height he of the supporting element 210 is less than 50% of the height ht of the supporting frame 200, effective elastic deformation may be difficult when the supporting element 210 presses the wire W. Also, when the height he of the supporting element 210 is more than 75% of the height ht of the supporting frame 200, the height he of the supporting element 210 is too high, and problems may occur in the reliability of the wire W support process, such as the supporting element 210 is excessively bent when the wire W is pressed. In an embodiment, to ensure the reliability of the supporting element 210 and effectively fix the wire W, the height he of the supporting element 210 may be about 60% to about 70% of the height ht of the supporting frame 200.

In an embodiment, the supporting element 210 may include a body 211 and a contact member 213.

The body 211 has an opening 211c on the inside and may be deformed when contacting the wire W. For example, the body 211 is an elastic member, and may be deformed in a longitudinal direction, a height direction, and a width direction of the body frame 100 upon contact with the wire W. In an embodiment, the body 211 may have a closed contour surrounding the opening 211c.

The shape of the body 211 is not particularly limited, and may include a pair of long sides 211a and a pair of short sides 211b in an embodiment. For example, as shown in FIG. 5, the body 211 may have a rectangular shape having the pair of long sides 211a in the longitudinal direction of the wire jig 10 and the pair of short sides 211b in the height direction of the wire jig 10. Before the body 211 deforms, the length of one of the pair of long sides 211a may be L, and the length of one of the pair of short sides 211b may be hb.

In an embodiment, to ensure the reliability according to the elastic deformation of the body 211 when pressing the wire W, a height hb of the body 211 may be 50% or less of the height he of the supporting element 210.

The contact member 213 may be arranged on one side of the body 211 and directly contact the wire W. For example, one or more contact members 213 may be arranged on a lower side of the body 211, for example, below one of the pair of long sides 211a of the body 211 to protrude toward the wire W. That is, the contact member 213 may be arranged on a lower surface of the body 211, the lower surface facing the wire W.

In an embodiment, a plurality of contact members 213 may be arranged. For example, as shown in FIG. 5, two contact members 213 may be arranged at a lower end portion of the body 211, and may be arranged to be spaced apart from each other in the longitudinal direction of the wire jig 10 by a distance d. Also, each of a plurality of contact members 213 may correspond to one wire W. That is, in a state where the plurality of wires W are arranged on the conveyor 41, the plurality of contact members 213 included in one supporting element 210 may contact different wires W.

In an embodiment, the contact member 213 may have a length I. The length I of the contact member 213 may be smaller than the length of the long side 211a of the body 211, and may be smaller than a distance d from an adjacent contact member 213. In an embodiment, the length I of the contact member 213 may be about 5 times to about 50 times the diameter of the wire W. In an embodiment, the length I of the contact member 213 may be about 10 times to about 30 times the diameter of the wire W. When the length I of the contact member 213 is smaller than 10 times the diameter of the wire W, it is difficult for the wire W to be arranged in a central region of the contact member 213 when the wire jig 10 descends, making it difficult to effectively support the wire W. When the length I of the contact member 213 exceeds 30 times of the diameter of the wire W, a weight of the supporting element 210 increases to increase a load applied to a connector 215, accordingly, damage may occur to the supporting frame 200, especially the connector 215, as the process is repeated.

In an embodiment, the length I of the contact member 213 may be about 10% to about 40% of a length L of the long side 211a of the body 211. In an embodiment, the length I of the contact member 213 may be about 15% to about 35% of the length L of the long side 211a of the body 211. When the length I of the contact member 213 is smaller than 10% of the length L of the long side 211a, the length I of the contact member 213 is too short, and it is difficult to effectively press the wire W. When the length I of the contact member 213 exceeds 40% of the length L of the long side 211a, the weight of the supporting element 210 increases to increase a load applied to the connector 215, accordingly, damage may occur to the supporting frame 200, especially the connector 215, as the process is repeated.

In an embodiment, the length I of the contact member 213 may be about 75% to about 95% of the distance d between the contact members 213. When the length I of the contact member 213 is smaller than 75% of the distance d between the contact members 213, it is difficult for the contact member 213 to effectively press the wire W. When the length I of the contact member 213 exceeds 95% of the distance d between the contact members 213, the weight of the supporting element 210 increases to increase a load applied to the connector 215, and accordingly, damage may occur to the supporting frame 200, especially the connector 215, as the process is repeated.

In an embodiment, a height hm of the contact member 213 may be 20% or less of the height he of the supporting element 210. In an embodiment, the height hm of the contact member 213 may be smaller than the height hb of the body 211. Accordingly, the reliability of the supporting element 210 may be ensured, that is, when the wire W is pressed, the wire W may be firmly supported while the supporting element 210 does not depart from the designated position and is not excessively deformed.

In an embodiment, the body 211 and/or the contact member 213 may be an elastic member. The body 211 and/or the contact member 213 include a deformable and elastic material, and accordingly, when the wire jig 10 contacts the wire W, the body 211 and/or the contact member 213 deform, so that the wire W may be more strongly pressed.

In an embodiment, the supporting element 210 may further include the connector 215. As shown in FIG. 5, one end of the connector 215 may be connected to the body 211 and another end thereof may be connected to the guide 230 such that the supporting element 210 and the guide 230 are connected to each other.

In an embodiment, the connector 215 may be arranged between a plurality of contact members 213. For example, as shown in FIG. 5, in a state where two contact members 213 are arranged on the long side 211a of the body 211, one end of the connector 215 may be arranged to vertically correspond to a position between the two contact members 213. In an embodiment, the connector 215 may be arranged to vertically correspond to a position in the middle of the two contact members 213 in a longitudinal direction of the body 211 or the wire jig 10. Accordingly, the supporting element 210 may uniformly press the plurality of wires W.

In an embodiment, the connector 215 may be an elastic member. That is, when the wire jig 10 contacts the wire W, in addition to the deformation of the body 211 and/or the contact member 213, the connector 215 may be compressed in the longitudinal direction of the connector 215 to press the wire W with more strength.

In an embodiment, to ensure the reliability according to the elastic deformation of the connector 215 when the wire W is pressed, a height hc of the connector 215 may be 50% or less of the height he of the supporting element 210, and the height hc of the connector 215 may be greater than the height hb of the body 211. In an embodiment, the height hb of the body 211 may be 90% or more of the height hc of the connector 215. In an embodiment, the height hb of the body 211 may be 95% or more of the height hc of the connector 215.

In an embodiment, the supporting element 210 may include a metal material, for example, SKH9 high-speed steel. Also, the body 211, the contact member 213, and the connector 215 of the supporting element 210 all include the same material and may be integrally formed.

The guide 230 is arranged on one side of the body frame 100 to connect the body frame 100 and the supporting element 210 to each other. In an embodiment, as shown in FIGS. 2 to 4, the guide 230 may have a bar or thin plate shape extending in the longitudinal direction of the wire jig 10, and both ends of the guide 230 may be connected to the inside of both ends of the body frame 100.

In an embodiment, a plurality of guides 230 may be provided. For example, as shown in FIGS. 2 and 3, a plurality of guides 230 may be arranged to be spaced apart from each other in the width direction of the wire jig 10.

In an embodiment, the guide 230 may be detachably connected to the body frame 100. For example, as shown in FIG. 4, the guide 230 may have an insertion protrusion 231 at each end thereof in the longitudinal direction. The insertion protrusion 231 may protrude downward from each end of the guide 230, so that the guide 230 may contact a larger area of the insertion groove 150. Also, the guide 230 may be detachably inserted into the insertion groove 150. Accordingly, the number of guides 230 included in the wire jig 10 and the number of supporting elements 210 according thereto may be adjusted by considering the number of wires W or the physical property of the wire W.

In an embodiment, the guide 230 may be an elastic member. That is, when the wire jig 10 contacts the wire W, in addition to the deformation of the body 211 and/or the contact member 213, the guide 230 may be compressed in the longitudinal direction of the guide 230 to press the wire W with more strength.

Next, referring to FIGS. 1 to 7, an operation of the wire jig 10 according to an embodiment is described.

As shown in FIG. 1, the solar cell C is conveyed to the solar cell dividing apparatus 30 by the solar cell conveying apparatus 20 to be divided into appropriate sizes. At the same time or at a different time, the wire W is conveyed on the conveyor 41 by the wire conveying apparatus 40. Also, at the same time or at a different time, the wire jig 10 is conveyed by the wire jig conveying apparatus 70. The transport head 55 of the transport apparatus 50 picks up the wire jig 10 by moving to a preset position through the first frame 51 and the second frame 53. Then, the transport head 55 moves onto the conveyor 41 on which the wire W is seated to place the wire jig 10 on the wire W.

In an embodiment, as shown in FIG. 6, the transport head 55 moves to a preset position so that the wire jig 10 contacts the wire W. In an embodiment, the tabbing apparatus 1 may include a sensor to check a contact state with the wire W. For example, the sensor may be arranged on the transport head 55 and/or the wire jig 10. The sensor may sense a contact state between the supporting frame 200 and the wire W.

The sensor may be an electromagnetic sensor, which may check a contact state through an electrical connection with the wire W, which is a conductor. Alternatively or additionally, the sensor may be a pressure sensor, which may check a contact state by measuring pressure between the wire W and the supporting frame 200. For example, when a current sensed by the sensor has a constant value or more, the tabbing apparatus 1 may determine that the contact state between the wire W and the wire jig 10 is good. Alternatively or additionally, when pressure sensed by the sensor has a constant value or more, the tabbing apparatus 1 may determine that the contact state between the wire W and the supporting frame 200 is good. Also, the transport apparatus 50 may maintain the contact state between the supporting frame 200 and the wire W based on the contact state sensed by the sensor.

Although in FIG. 6 one supporting element 210 is shown as being in contact with two wires W, the disclosure is not limited thereto. When one of the plurality of supporting elements 210 contacts the wire W, the remaining supporting elements 210 may also contact the wire W. That is, the plurality of supporting elements 210 may contact corresponding wires W at the same time.

Next, the tabbing apparatus 1 may press the wire W with the wire jig 10 by moving the transport head 55 downward. In an embodiment, as shown in FIG. 7, in a state where the supporting element 210 contacts the wire W, the wire jig 10 presses the wire W downward by the transport head 55, that is, in a direction perpendicular to the surface of the ground or the conveyor 41. Accordingly, while the shape of the supporting element 210 changes, the wire W presses the conveyor 41, so that the wire W is firmly supported.

For example, as shown in FIG. 7, as the body 211, which is an elastic member, receives a force in the vertical direction, the long side 211a of the body 211 bends downward, a length L1 of the long side 211a of the body 211 changes to L2, and a length hb1 of the short side 211b changes to hb2. As the shape of the body 211 changes, the wire W may be supported more by a restoring force to restore the body 211 to an original shape of the body 211. Also, when the supporting frame 200 entirely includes an elastic member, components other than the body 211 also elastically deform by contacting the wire W. For example, the contact member 213, the connector 215, and the guide 230 may also elastically deform in a direction perpendicular to a height direction of the wire W while contacting the wire W.

In the drawing, only the body 211 is shown as an elastic member, but the disclosure is not limited thereto. As described above, in addition to the body 211, the contact member 213, the connector 215, and/or the guide 230 may also be elastic members. Accordingly, while the shapes of the contact member 213, the connector 215 and/or the guide 230 deform, the wire W may be strongly supported by restoring forces of the contact member 213, the connector 215 and/or the guide 230.

In an embodiment, the transport head 55 may constantly maintain a pressurized state on the wire W through the sensor. In an embodiment, the transport head 55 may press the wire jig 10 against the wire W so that a current value and/or a pressure value sensed by the sensor is maintained in a preset range.

Thereafter, when a process of seating the solar cell C on the wire W is finished, the transport head 55 picks up the wire jig 10 and releases the pressurized state. Thereafter, the solar cell C and the wire W are moved to the bonding apparatus 60 through the wire conveying apparatus 40 to be electrically connected to each other to form a solar cell module.

Through this configuration, the wire jig 10 according to an embodiment and the tabbing apparatus 1 including the same may prevent lifting of the wire W or displacement of the wire W when the solar cell C is connected to the wire W, so that the solar cell C and the wire W may be connected to each other well at a designated position.

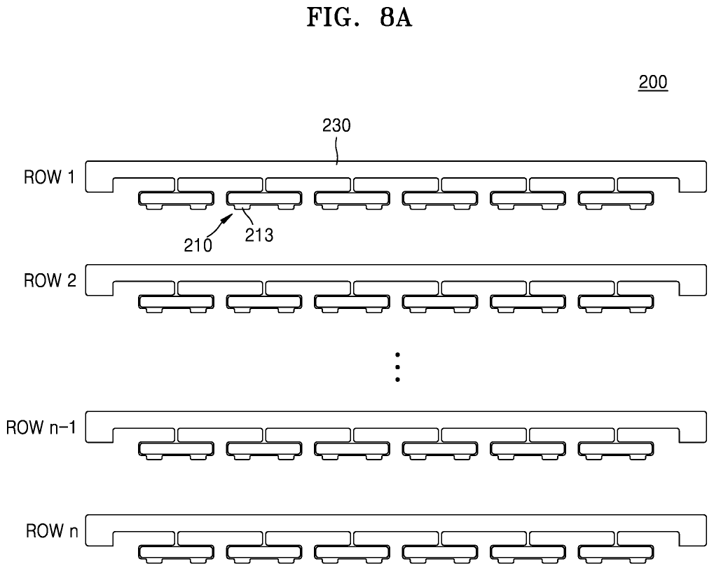

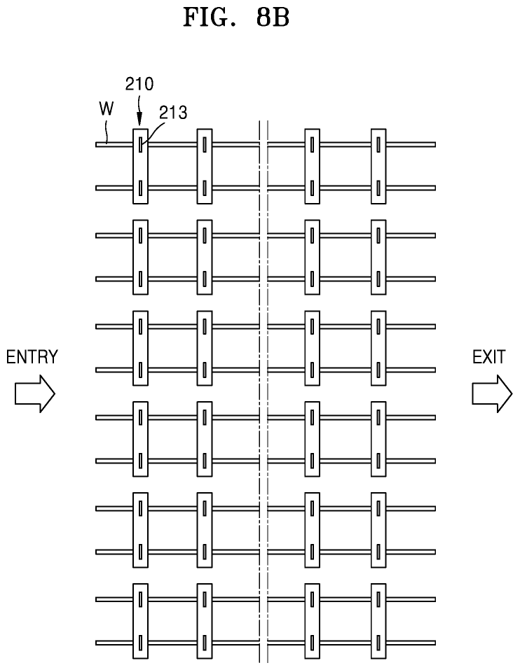

FIGS. 8A and 8B to 11A and 11B show supporting frames 200 to 200C according to other embodiments and a support state of the wire W according to the supporting frames 200 to 200C. Referring to FIGS. 8A and 8B to 11A and 11B, the supporting frame 200 according to an embodiment may include the same number of support elements 210 or may include different numbers of support elements 210 depending on a position where the supporting frame 200 is arranged.

First, FIGS. 8A and 8B show the supporting frame 200 according to the embodiment described above and a support state of the wire W according to the supporting frame 200. The supporting frames 200 are spaced apart from each other in a width direction of the body frame 100, that is, in an entry direction of the wire W, and are arranged inn rows. Here, n is a natural number greater than or equal to 1. At this time, n supporting frames 200 may be spaced apart from each other at equal intervals. Also, the plurality of supporting frames 200 may be sequentially arranged from row 1 to row n in the entry direction of the wire W.

In an embodiment, each supporting frame 200 may be in the same number and arrangement of supporting elements 210. For example, each supporting frame 200 may include a plurality of supporting elements 210, each supporting element 210 may include a plurality of contact members 213. In an embodiment, as shown in FIGS. 8A and 8B, one supporting frame 200 may include six supporting elements 210, and one supporting element 210 may include two contact members 213. Also, in the longitudinal direction of the body frame 100, intervals between the supporting elements 210 may be constant in all of the supporting frames 200. Also, each supporting element 210 and the contact member 213 included therein may all be positioned on a line parallel to the entry direction of the wire W. In addition, in the width direction of the body frame 100, intervals between the supporting frames 200 may be constant. Here, an interval between the contact members 213 included in one supporting frame 200 may correspond to an interval between adjacent wires W. Accordingly, the wire jig 10 may uniformly support all the plurality of wires W during a bonding process between the solar cell C and the wire W.

Although FIGS. 8A and 8B show that one supporting frame 200 includes six supporting elements 210, the number thereof is not particularly limited. For example, one supporting frame 200 may include more or less than six supporting elements 210.

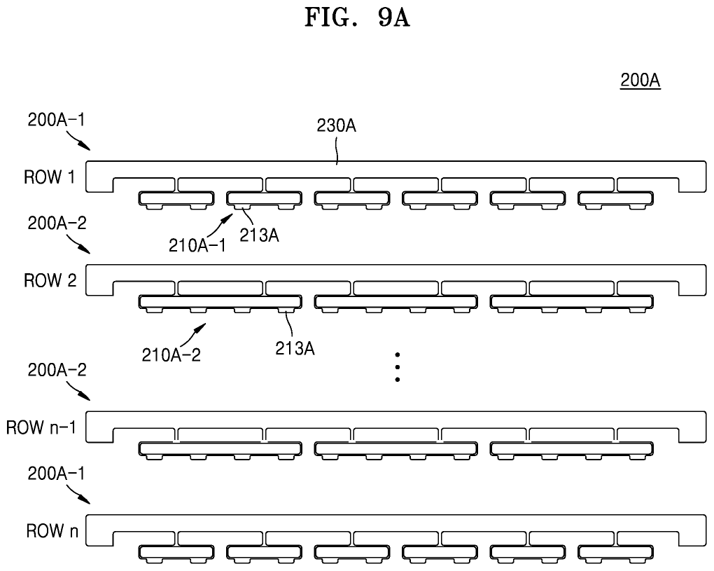

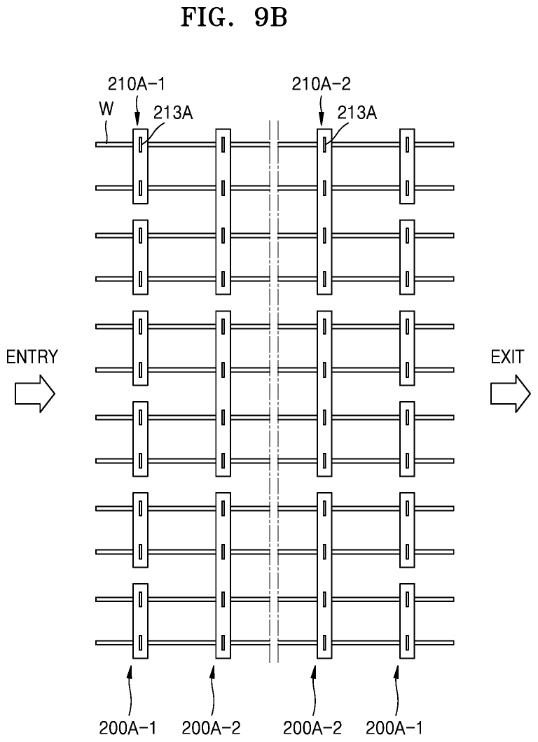

FIGS. 9A and 9B show a supporting frame 200A according to another embodiment and a support state of the wire W according to the supporting frame 200A. The supporting frames 200A are arranged in n rows in the width direction of the body frame 100, that is, the entry direction of the wire W. Here, n is a natural number greater than or equal to 1.

In an embodiment, at least one of a plurality of supporting frames 200A may be different from the rest of the supporting frames 200A in the number and arrangement of supporting elements 210A. For example, the number and arrangement of the supporting elements 210A may be the same as those of the supporting frames 200A in row 1 and row n. In an embodiment, as shown in FIG. 9A, the plurality of supporting frames 200A may include a plurality of first supporting frames 200A-1 and a plurality of second supporting frames 200A-2. Like the supporting frame 200 described above, the first supporting frame 200A-1 may include a plurality of first supporting elements 210A-1 each having two contact members 213A and having the same size and shape. Also, the first supporting frame 200A-1 may correspond to the supporting frames 200A in row 1 and row n.

Also, the second supporting frame 200A-2 may include a plurality of second supporting elements 210A-2 each having three or more contact members 213A and having the same size and shape. Also, the second supporting frames 200A-2 may correspond to the rest of the supporting frames 200A except the supporting frames 200A in row 1 and row n. For example, the second supporting element 210A-2 may include four contact members 213A and may support the plurality of wires W corresponding to the number of contact members 213A. That is, the supporting frames 200A in row 1 and row n, that is, the first supporting frames 200A-1 may include more supporting elements 210A than the rest of the supporting frames 200A, that is, the second supporting frames 200A-2. In addition, the number of contact members 213A included in each of the second supporting frames 200A-2 may be the same as the number of contact members 213A included in each of the supporting frames 200A of row 1 and row n, that is, the first supporting frame 200A-1.

Through this configuration, the wire jig 10 arranges a relative large number of first supporting elements 210A-1 in the first supporting frame 200A-1 arranged in an entry direction and an exit direction, where an alignment state of the wire W is particularly important, to accurately support the wire W, and relatively reduce the number of second supporting elements 210A-2 in the second supporting frame 200A-2 arranged between the first supporting frames 200A-1 to easily process the wire jig 10.

Also, one second supporting element 210A-2 supports a larger number of wires than the plurality of wires W primarily aligned by the first supporting elements 210A-1 at the same time, and poor alignment of wires W due to misalignment between the different supporting elements 210A may be more effectively prevented.

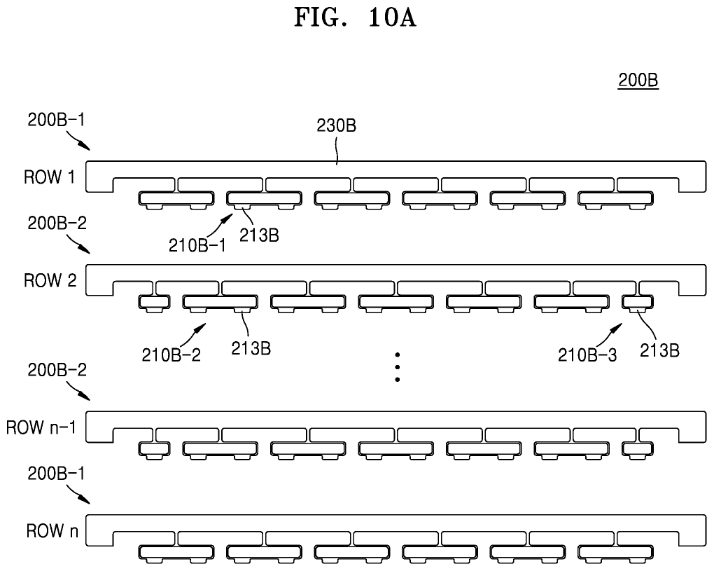

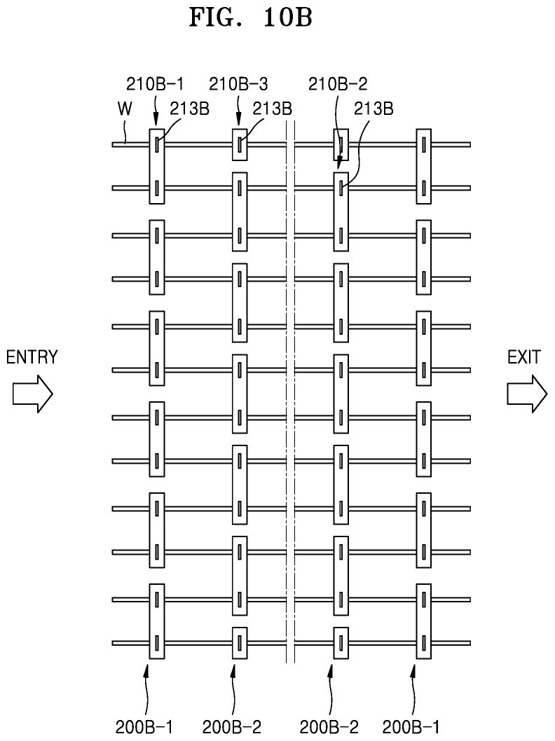

FIGS. 10A and 10B show a supporting frame 200B according to another embodiment and a support state of the wire W according to the supporting frame 200B. The supporting frames 200B are arranged inn rows in the width direction of the body frame 100, that is, the entry direction of the wire W. Here, n is a natural number greater than or equal to 1.

In an embodiment, at least one of a plurality of supporting frames 200B may be different from the rest of the supporting frames 200B in the number and arrangement of supporting elements 210B. For example, a plurality of supporting frames 200B may include a first supporting frame 200B-1 including a plurality of first supporting elements 210B-1 and a second supporting frame 200B-2 including a plurality of second supporting elements 210B-2.

In an embodiment, the supporting frames 200B in row 1 and row n are the first supporting frames 200B-1, and the number and arrangement of supporting elements 210B may be the same. In an embodiment, as shown in FIG. 10A, like the supporting frame 200 described above, the first supporting frame 200B-1 may include the plurality of first supporting elements 210B-1 each having two first contact members 213B and having the same size and arrangement.

Also, the rest of supporting frames 200B, except the supporting frames 200B in row 1 and row n, are the second supporting frames 200B-2, and may include the plurality of second supporting elements 210B-2 each having two contact members 213B like the supporting frame 200 described above and having the same size and shape.

In an embodiment, the second supporting element 210B-2 may be alternately arranged with the first supporting element 210B-1. For example, as shown in FIG. 10A, the second supporting element 210B-2 may be arranged to overlap two first supporting elements 210B-1 in the width direction of the body frame 100, that is, the entry direction of the wire W. That is, as shown in FIG. 10B, one second supporting element 210B-2 may be arranged between two first supporting elements 210B-1, which are spaced apart from each other. Similarly, one first supporting element 210B-1 may be arranged between two second supporting elements 210B-2, which are spaced apart from each other.

In an embodiment, the second supporting frame 200B-2 may including one or more third supporting elements 210B-3. The third supporting element 210B-3 may be arranged at least one end of both ends of the second supporting frame 200B-2 in the longitudinal direction. For example, as shown in FIG. 10A, a pair of third supporting elements 210B-3 may be respectively arranged at both ends of the second supporting frame 200B-2 in the longitudinal direction. The third supporting element 210B-3 may have fewer contact members 213B than that of the second supporting element 210B-2. For example, the third supporting element 210B-3 may have one contact member 213B.

That is, the supporting frames 200B in row 1 and row n, that is, the first supporting frames 200B-1, may include less supporting elements 210B than the rest of the supporting frames 200B, that is, the second supporting frames 200B-2.

Also, the number of contact members 213B included in each of the second supporting frames 200B-2 may be the same as the number of contact members 213B included in each of the supporting frames 200B of row 1 and row n, that is, the first supporting frame 200B-1.

Accordingly, in the wire jig 10, the first supporting element 210B-1 and the second supporting element 210B-2 have different centers of gravity and support the wire W, so that the plurality of wires W may be supported more reliably.

In another embodiment, the first supporting frame 200B-1 and the second supporting frame 200B-2 may be alternately arranged. That is, in the entry direction of the wire W, the first supporting frame 200B-1 and the second supporting frame 200B-2 may be repeatedly arranged with each other. In this case, the supporting frames 200B of row 1 and row n may be the first supporting frames 200B-1.

That is, in an embodiment, based on the entry direction of the wire W, the number of supporting elements 210B arranged in each supporting frame 200B may increase and decrease repeatedly. Also, the number of contact elements 213B arranged in each of the supporting frames 200B may the same.

Accordingly, the third supporting elements 210B-3 may be arranged in a space obtained by the second supporting elements 210B-2 being alternately arranged with the first supporting elements 210B-1 to firmly support the plurality of wires W. Also, because the third supporting element 210B-3 has only one contact member 213B has a shorter length than that of the first supporting element 210B-1 and the second supporting element 210B-2, the center of gravity of the third supporting element 210B-3 coincides with the center of gravity of the wire W to more firmly support the wire W.

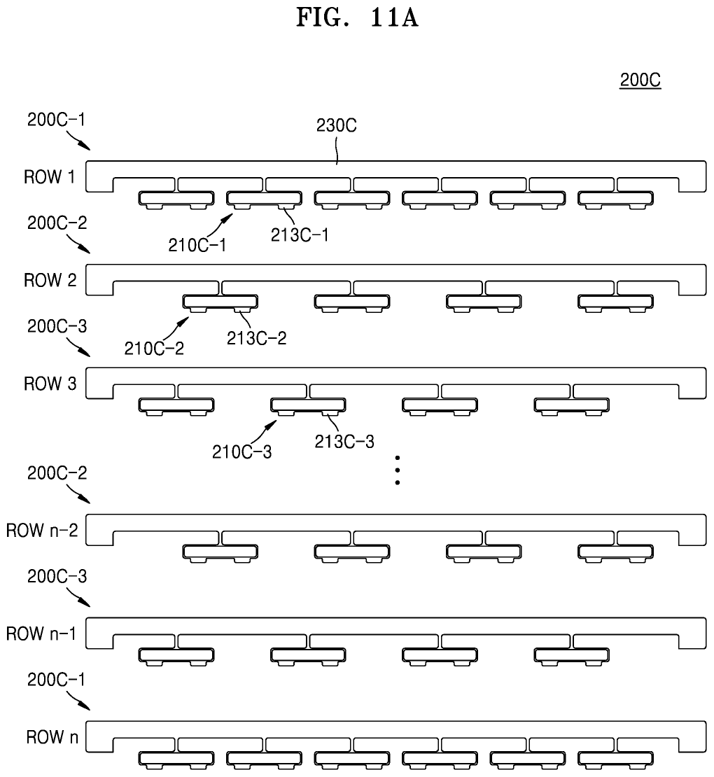

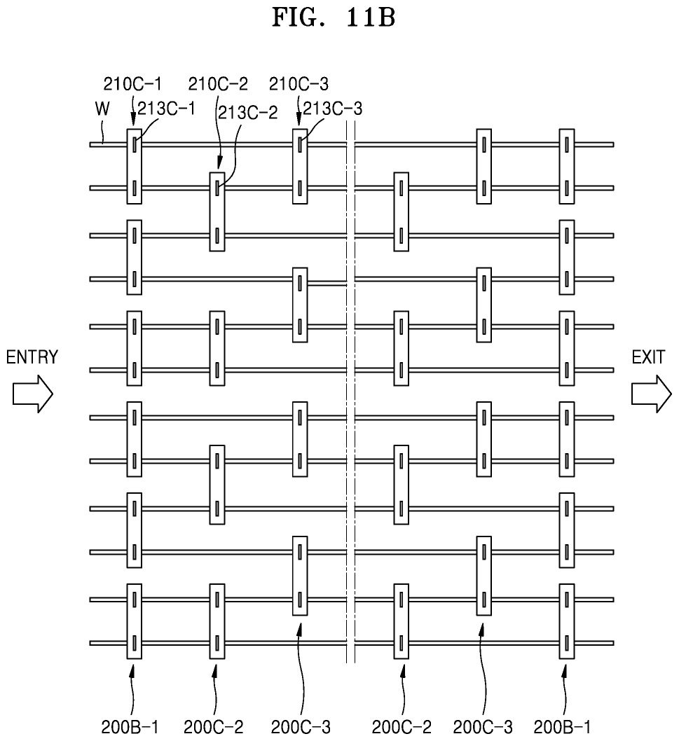

FIGS. 11A and 11B show a supporting frame 200C according to another embodiment ad a support state of the wire W according to the supporting frame 200C. The supporting frames 200C are arranged inn rows in the width direction of the body frame 100, that is, the entry direction of the wire W. Here, n is a natural number greater than or equal to 1.

In an embodiment, at least one of a plurality of supporting frames 200C may be different from the rest of the supporting frames 200C in the number and arrangement of supporting elements 210C. For example, as shown in FIG. 11A, a plurality of supporting frames 200C may include a plurality of first supporting frames 200C-1, a plurality of second supporting frames 200C-2, and a plurality of third supporting frames 200C-3. Also, like the supporting frame 200 described above, the supporting frames 200C of row 1 or n row are the first supporting frames 200C-1, which may include a plurality of first supporting elements 210C-1 each having two contact members 213C-1 and having the same size and arrangement.

Also, the remaining supporting frames 200C, except the supporting frames 200C in row 1 and row n, are the second supporting frames 200C-2 and the third supporting frames 200C-3, and the second supporting frames 200C-2 and the third supporting frames 200C-3 may include a plurality of second supporting elements 210C-2 and a plurality of third supporting elements 210C-3, wherein the plurality of second supporting elements 210C-2 and the plurality of third supporting elements 210C-3 have the same size and arrangement and respectively have two contact members 213C-2 and two contact members 213C-3.

In an embodiment, the plurality of second supporting elements 210C-2 and the plurality of third supporting elements 210C-3 included in the second supporting frame 200C-2 and the third supporting frame 200C-3 may be arranged to be spaced apart from each other in the longitudinal direction of the body frame 100. For example, as shown in FIGS. 11A and 11B, the plurality of second supporting elements 210C-2 included in the second supporting frame 200C-2 may be arranged to be spaced apart from each other by an interval corresponding to one wire W. Similarly, the plurality of third supporting elements 210C-3 included in the third supporting frame 200C-3 may be arranged to be spaced apart from each other by an interval corresponding to one wire W.

Accordingly, in the width direction of the body frame 100, some of the plurality of second supporting elements 210C-2 and the plurality of third supporting elements 210C-3 are arranged to overlap two adjacent first supporting elements 210C-1, and the rest may be arranged on the same line as the first supporting element 210C-1.

In an embodiment, the second supporting frame 200C-2 and the third supporting frame 200C-3 may be alternately arranged.

In an embodiment, the plurality of second supporting elements 210C-2 and the plurality of third supporting elements 210C-3 may be alternately arranged. For example, as shown in FIGS. 11A and 11B, second supporting elements 210C-2 included in the second supporting frame 200C-2 in row 2 and the third supporting elements 210C-3 included in the third supporting frame 200C-3 in row 3 may be arranged to partially overlap each other in the width direction of the body frame 100.

That is, the supporting frames 200C in row 1 and row n, that is, the first supporting frames 200C-1, may include more supporting elements 210C than the rest of supporting frames 200C, that is, the second supporting frames 200C-2 and the third supporting frames 200C-3. Also, the number of the supporting elements 210C included in the second supporting frame 200C-2 may be equal to the number of supporting elements 210C included in the third supporting frame 200C-3.

Also, the number of contact members 213C included in each of the supporting frames 200C of row 1 and row n, that is, the first supporting frame 200C-1, may be different from the number of contact members 213C included in each of the second and third supporting frames 200C-2 and 200C-3. For example, the number of contact members 213C included in each of the first supporting frames 200C-1 may be greater than the number of contact members 213C included in each of the second and third supporting frames 200C-2 and 200C-3.

As described above, the plurality of second supporting elements 210C-2 and the plurality of third supporting elements 210C-3 included in the supporting frames 200C arranged between the supporting frames 200C of row 1 and row n are arranged to cover spaces corresponding to the wires W, and the wire W may be firmly supported even with a relatively small number of supporting elements 210C.

A wire jig according to an embodiment and a tabbing apparatus including the same may achieve an improved wire supporting performance while configuring the wire jig simply and compactly.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A wire jig configured to support a plurality of wires, the wire jig comprising:
a body frame having a window on an inside of the body portion; and
a plurality of supporting frames arranged to correspond to the window, each supporting frame comprising a plurality of supporting elements contacting the plurality of wires, and arranged to form n rows (n is a natural number greater than 1) in a width direction of the body frame,
wherein the plurality of supporting frames are sequentially arranged from a 1^{st} row to an n^{th} row, and
wherein the plurality of supporting elements included in any one of the supporting frames have a different arrangement from the plurality of supporting elements included in at least one of the other supporting frames.

2. The wire jig of claim 1, wherein each of the plurality of supporting elements comprises:
a body; and
at least one contact member arranged on a lower surface of the body, the lower surface facing the wire, and protruding toward the wire.

3. The wire jig of claim 2, wherein a number of supporting elements included in each of the supporting frame of the 1^{st} row and the supporting frame of the n^{th} row is greater than a number of supporting elements included in another supporting frame.

4. The wire jig of claim 2, wherein the plurality of supporting elements included in the supporting frame of the 1^{st} row are in the same number and arrangement as the plurality of supporting elements included in the supporting frame of the n^{th} row.

5. The wire jig of claim 4, wherein the plurality of supporting elements included in the supporting frame of each of the 1^{st} row and the supporting frame of the n^{th} row have a smaller number of contact members than the plurality of supporting elements included in each of the other supporting frames.

6. The wire jig of claim 1, wherein the plurality of supporting frames comprise:
a plurality of first supporting frames each of which comprises a plurality of supporting elements, each having two contact members; and
a plurality of second supporting frames each of which comprises a plurality of second supporting elements, each having two contact members and arranged to overlap two adjacent first supporting elements included in each of the first supporting frames in a width direction of the body frame.

7. The wire jig of claim 6, wherein the plurality of first supporting frames and the plurality of second supporting frames are alternately arranged.

8. The wire jig of claim 6, wherein each of the plurality of second supporting frames further comprises a pair of third supporting elements arranged at both ends in a longitudinal direction of the body frame to arrange the plurality of second supporting elements between the pair of third supporting elements, and
wherein each of the third supporting elements has one contact member.

9. The wire jig of claim 1, wherein the plurality of supporting elements included in at least one supporting frame are arranged zigzag with the plurality of supporting elements included in an adjacent supporting frame in a width direction of the body frame.

10. The wire jig of claim 1, wherein the plurality of supporting elements are different by row in terms of at least one of a number of the supporting elements, a position of the supporting elements, and a number of contact members included in each of the supporting elements, and
wherein the contact member is configured to contact each of the wires.

11. A tabbing apparatus configured to connect a solar cell and a wire to each other, and comprising a wire jig configured to support the wire and a transport apparatus configured to move the wire jig, wherein the wire jig is configured to support a plurality of wires, the wire jig comprising:
a body frame having a window therein; and
a plurality of supporting frames arranged to correspond to the window, comprising a plurality of supporting elements configured to contact the plurality of wires, and arranged to form n rows (n is a natural number greater than 1) in a width direction of the body frame,
wherein the plurality of supporting frames are sequentially arranged from a 1^{St} row to an n^{th} row, and
wherein the plurality of supporting elements included in any one of the supporting frames in the 1^{st} row to the n^{th} row have a different arrangement from the plurality of supporting elements included in at least one of the other supporting frames.
